(19) United States
(12) Patent Application Publication
(10) Pub. No.: US 2026/0301769 A1
(43) Pub. Date: Oct. 1, 2026

(54) Hybrid Analog Digital Audio Format

(71) Applicant: Ceramic Data Solutions GmbH, Gmunden (AT)

(72) Inventors: Martin Kunze, Gmunden (AT); Sebastian Kirsch, Bad Goisern (AT); Christian Pflaum, Bernried (DE)

(21) Appl. No.: 19/490,200

(22) PCT Filed: Jun. 7, 2023
(86) PCT No.: PCT/EP2023/065271

§ 371 Date: Dec. 4, 2025

(51) Int. Cl. G11B 20/10; G10L 19/002; G10L 19/008; G11B 20/02

(52) U.S. Cl. CPC G11B 20/10027; G10L 19/002; G11B 20/02; G11B 20/10527; G10L 19/008; G11B 2020/10546

(57) ABSTRACT

The present invention relates to a method of storing a digital audio signal in a hybrid format and to a method of reading out analog audio information, enhanced analog audio information or digital audio information from a digital audio signal in a hybrid analog digital format.

### INTRODUCTION

The present invention relates to a method of storing a digital audio signal in a hybrid format and to a method of reading out analog audio information, enhanced analog audio information or digital audio information from a digital audio signal in a hybrid analog digital format.

WO 2021/028035 discloses a method for long-term storage of information utilizing a coated ceramic substrate and encoding information by ablating or otherwise manipulating the coating by means of a laser beam. Said information may be encoded in an analog format using, e.g., letters, symbols, images and the like or in a digital format using, e.g., a QR code.

The present invention aims at expanding this concept to audio data. However, in view of the long-term storage context utilizing currently known audio data formats may not be appropriate as future generations might not be able to decode such audio data. It is thus an object of the present invention to provide a new audio format which allows for both easy retrieval of at least some basic information with simple techniques and storing detailed digital audio information.

This object is achieved with the methods of the independent claims. Preferred features are described, inter alia, in the dependent claims.

### SUMMARY

Accordingly, the present invention relates, according to a first aspect, to a method of storing a digital audio signal in a hybrid analog digital format, which can be read out both with analog and digital reading techniques. The method comprises providing a digital audio signal with a series of samples, each sample representing an amplitude and having 1 Sign Bit representing the sign (plus or minus) of said audio signal sample, at least 3-4 (preferably 3) Segment Bits representing the number of segments of the audio signal sample and at least 4-10 (preferably 4, 6 or 8) Quantification Bits representing the quantification of the relevant segment of the audio signal sample. The method further comprises storing each sample of the digital audio signal in a hypothetical double matrix, each hypothetical matrix of the double matrix containing m columns and n lines, wherein one matrix of the double matrix represents a positive audio signal sample and the other matrix of the double matrix represents a negative audio signal sample. Each line of each matrix represents a segment of the audio signal sample. Storing the digital audio signal sample in the double matrix comprises marking certain elements of the hypothetical double matrix according to the following rules: selecting the matrix of the double matrix representing the sign represented by the Sign Bit, i.e. the positive matrix for a positive signal and the negative matrix for a negative signal; marking all elements of all lines of said selected matrix representing the segments represented by the Segment Bits; and marking certain elements in one further line of said selected matrix representing the relevant segment adjacent to the segments represented by the Segment Bits with a predetermined pattern corresponding to the quantification of the relevant segment represented by the Quantification Bits.

In other words, the hypothetical matrix (which only represents potential points or areas for markings) is partially or fully filled up from bottom to top leading to a large number of marked “pixels” (matrix elements) for a signal with large intensity and a smaller number of marked “pixels” for a signal with smaller intensity. The number of completely filled lines provides thus a rough estimate of the signal intensity with the more precise intensity being encoded in the specific pattern of marked elements (“pixels”) within the further (typically top-most) line. This allows for reading out the hybrid code with a rough analog technique and a more precise digital technique as further elucidated below.

Preferably, each predetermined pattern for each quantification is defined in a look-up table. Different look-up tables may be provided for different encoding qualities as will be further elucidated below with reference to the examples.

Preferably, the positive signal matrix and the negative signal matrix are arranged adjacent to each other and are separated by a hypothetical separation line and the lines representing the segments are filled up starting from the separation line (e.g. from bottom to top in case of the positive signal matrix and from top to bottom in case of the negative signal matrix). Of course, only one of the two hypothetical matrices of each “double matrix” will be present, i.e. partially filled up with marked elements, for each sample, which can only be either positive or negative.

Preferably, the digital audio signal sample represents an amplitude or intensity and the amplitude or intensity scales approximately exponentially with the number of fully marked lines. This is due to the physiological properties of the human ear as will be evident to the skilled person. In other words, the signal is more precise for larger amplitudes than for lower amplitudes.

Preferably, the series of samples of the digital audio signal are stored in adjacent double matrices. In other words, multiple hypothetical double matrices (with only one matrix being partially marked depending on the sign) form a line of data or code which, however, provides the visual impression of a varying signal or a wave. This may provide a hint towards future generations that audio data is encoded on the corresponding data carrier.

Preferably, storing the digital audio signal sample in the double matrix comprises providing a data carrier and creating a plurality of recesses in a surface of the data carrier by using a laser in order to mark certain elements of the double matrix. Preferably, the shape of the recesses is cylindrical or cone-like. The cross-section of the recesses may be cylindrical, elliptical, rectangular, square or the like. In view of the used laser ablation cylindrical recesses are most preferred. Preferably, providing a data carrier comprises providing a substrate and coating the substrate with a first coating of a material different from the material of the substrate and wherein creating a plurality of recesses in a surface of the data carrier comprises creating a plurality of recesses in the first coating.

Preferably, the recesses extend through the coating towards the substrate.

Preferably, the substrate is a ceramic substrate. This is particularly advantageous in view of the envisage long-term storage properties as outlined in WO 2021/028035.

Preferably, the substrate comprises a glassy transparent ceramic material or a crystalline ceramic material and/or wherein the substrate comprises one or a combination of: sapphire (Al₂O₃), silica (SiO₂), zirconium silicate (Zr(SiO₄)), ZrO₂, boron oxide, sodium oxide, potassium oxide, lithium oxide, zinc oxide and magnesium oxide. This is particularly advantageous for the analog read-out technique discussed further below.

The present invention further relates, according to a second aspect, to a method of reading out analog audio information from a digital audio signal in a hybrid format stored according to the first aspect. The method comprises generating an audio amplitude based on the number of marked elements within the double matrix wherein the sign of said audio amplitude is defined by the matrix of the double matrix containing marked elements.

Preferably, the number of marked elements within the double matrix is extracted by illuminating the double matrix from one side and measuring the reflected light or the transmitted light amplitude on the opposite side. As will be appreciated by the skilled person, this corresponds to a well-known technique for reading out audio data from, e.g., analog films. Accordingly, the hybrid data format of the present invention is, at least to a certain extent, accessible by well-known analog techniques. Of course, the signal will be blurred, yet still discernible.

The present invention further relates, according to a third aspect, to a method of reading out enhanced analog audio information from a digital audio signal in a hybrid format stored according to the first aspect. The method comprises generating an audio amplitude based on the number of fully marked lines and on the number of marked elements within the further line within the double matrix, wherein the sign of said audio amplitude is defined by the matrix of the double matrix containing marked elements, and wherein the audio amplitude is based on weighting each line with a different weighting coefficient.

Preferably, the weighting coefficients for lines 0, 1, 2, . . . , n−1 scale with 2⁰, 2¹, 2², . . . , 2ⁿ⁻¹.

The present invention further relates, according to a fourth aspect, to a method of reading out digital audio information from a digital audio signal in a hybrid format stored according to the first aspect. The method comprises generating an audio amplitude based on the number of fully marked lines, on the number of marked elements within the further line and on the pattern of marked elements within the further line within the double matrix, wherein the sign of said audio amplitude is defined by the matrix of the double matrix containing marked elements, and wherein the audio amplitude is based on weighting each line with a different weighting coefficient and on allocating a predetermined amplitude to the pattern of marked elements based on a look-up table.

Preferably, the weighting coefficients for lines 0, 1, 2, . . . , n−1 scale with 2⁰, 2¹, 2², . . . , 2ⁿ⁻¹.

Preferably, generating an audio amplitude is repeated for each of a series of double matrices in order to generate an audio signal with a series of samples.

### BRIEF DESCRIPTION OF THE DRAWINGS

The present invention will be further elucidated with reference to the Figures.

FIG. 1 shows Prior Art—see https://en.wikipedia.org/wiki/Optical_sound.

FIG. 2 shows a Hybrid Analog Digital Format—Image (cf. WO 2022/228675) & Audio.

FIG. 3a shows a Hybrid Analog Digital Format—Stereo audio including header with compression table (top line).

FIG. 3b shows a Hybrid Analog Digital Format—Multi-channel audio including header with compression table (top line).

FIG. 3c shows a Hybrid Analog Digital Format—Stereo audio signal & explanation of compression table (top line).

FIG. 4a shows a Compression Table for Hybrid Analog Digital Format.

FIG. 4b shows an Analog compression table.

FIG. 4c shows a Digitally compression table.

FIG. 5a shows a PCM System with Analog Companding.

FIGS. 5b-1 and 5b-2 show a Digitally Companded PCM System.

FIGS. 6a and 6b show a Companding Process-Compression and Expansion of Dynamic Range.

FIG. 7a shows an Analog Companding PCM System and hybrid analog digital (HAD) audio en-/decoder.

FIG. 7b shows a Digitally Companded PCM System and hybrid analog digital (HAD) audio en-/decoder.

FIG. 8a shows a PCM System with digital companding using non-linear function with segment identifier.

FIG. 8b shows an Encode in hybrid analog digital audio samples-Sign & Segment.

FIGS. 8c-1 to 8c-4 show an Encode in hybrid analog digital audio samples Quantization within segment.

FIGS. 8d-1 to 8d-3 show a look up table.

FIG. 9a shows an Analog Code—Linear Decoding—Amplitude proportional to white areas.

FIG. 9b shows an Analog Code—Non-Linear Decoding enabling higher dynamic range.

FIG. 9c shows a Digital PCM decoding with simple 10 look up table.

FIG. 9d shows a Digital PCM decoding with 16-2 m line look up table.

FIG. 9 e shows a Direct Digital Code-Amplitude directly coded in 2×8 Bit in top and bottom line.

### DETAILED DESCRIPTION

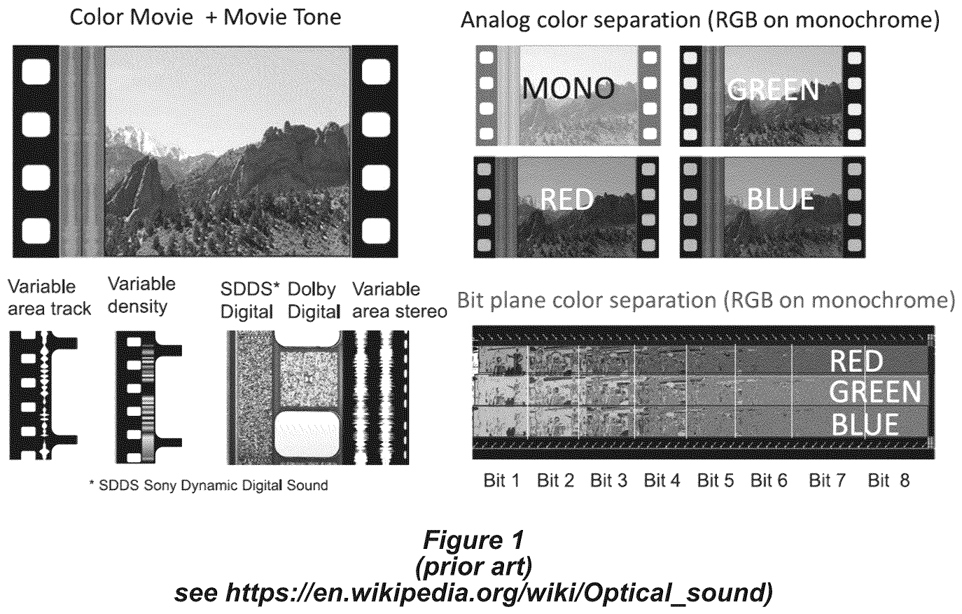

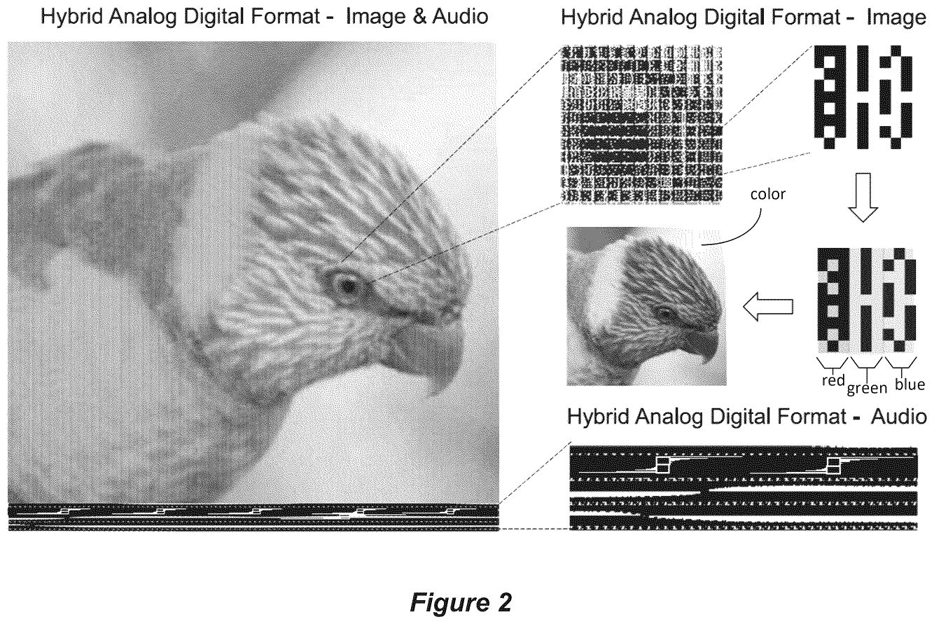

FIG. 1 summarizes the prior art for recordings of images and sound: Analog movies on film last up to about 100 years, while digitized material copies need to be copied every 5-10 years onto a new digital medium. Therefore, the movie industry is experimenting with several methods of color separation and semi-digitized bit plan copies to preserve valuable content for longer periods. Movie sound is traditionally copied on the side as analog black and white or grey values or as digital bit stream in parallel to the image. So far, no method has been found which allows analog and digital data storage in one single format.
FIG. 2 shows an example of the inventive Hybrid Analog Digital Format, the image format already being described in WO 2022/228675, which allows analog reconstruction of grey and color images and movies alike. At the same time, the Hybrid Analog Digital Format allows to digitally encode more information by using pixel by pixel color separation by a sub-micron 10×10 matrix. The present invention now expands this concept of a Hybrid Analog Digital Format to audio signals, which can be decoded dependent on the technical standard available to future generations. To separate the positive and negative waves, we use two 10×10 matrices (so-called “double matrix”) initially which can be generalized to an n×m matrix, where preferably n>=10 and m>=10. A particular favorable case is a 20×20 matrix, which allows higher resolution and dynamic range of the individual sample value. Hybrid analog digital audio format (HAD audio) is based on Pulse Code Modulation with a minimal sampling frequency at least twice of the audio range (Nyquist-Shannon Criterium). For practical reasons, that can be 44 kHz (CD) or 48-96 kHz (movie).

Furthermore, the top line of the upper n x m matrix contains the sign (+/−) and the higher value bits, while the bottom line of the lower n x m matrix contains the lower value bits. Therefore, HAD audio format takes the future discoverer on a journey through technical history and allows a step-by-step quality improvement dependent on the technical knowledge of the discoverers. Steps:
1. analog linear PCM—2. analog non-linear PCM—3. Digital PCM decoding with simple 10 intensity levels without look up table—4. Digital PCM decoding with 16-2^{m} lines look up table—5. Digital PCM decoding with upper and lower line.

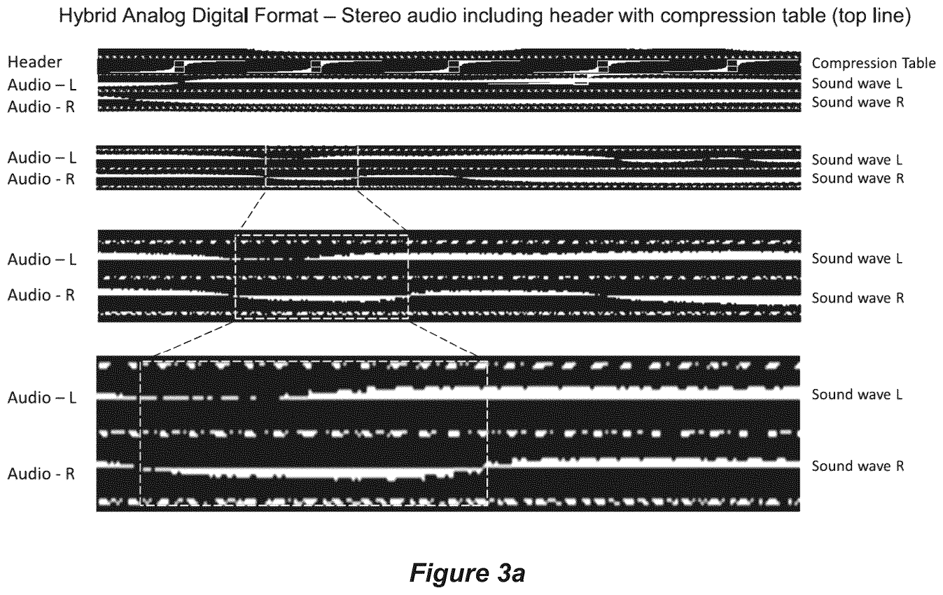

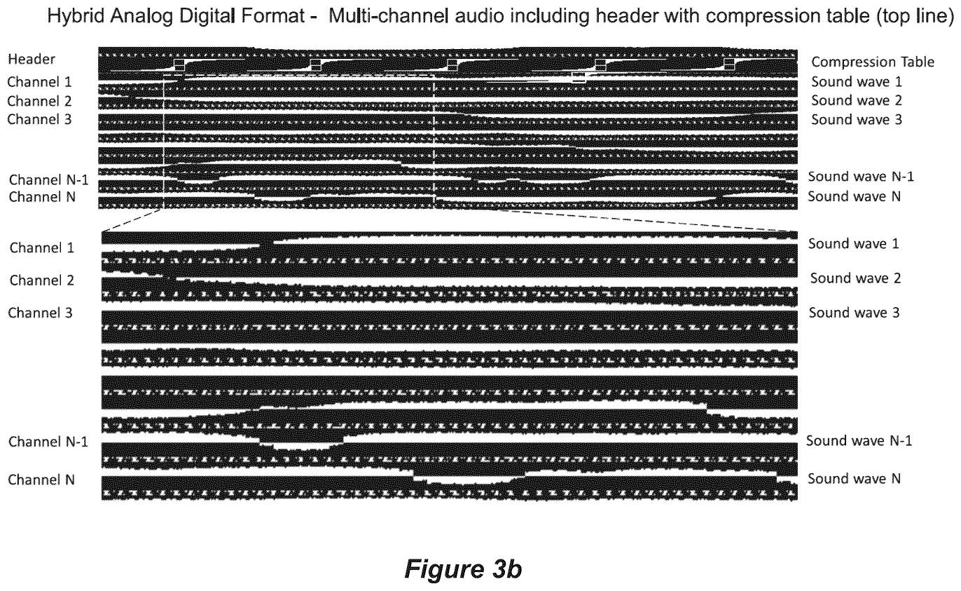

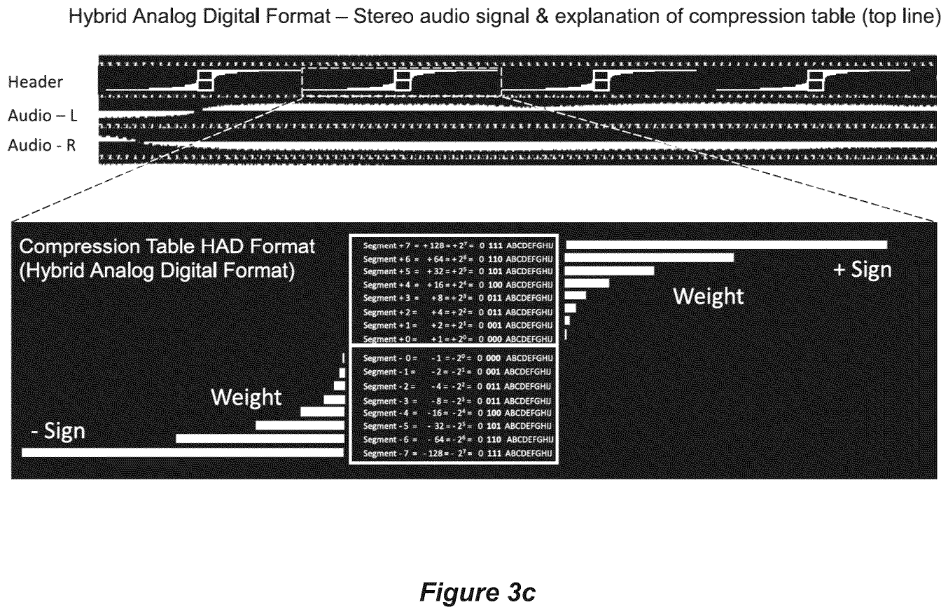

FIG. 3a shows an example of the inventive Hybrid Analog Digital Format in different resolutions. FIG. 3b shows an example of the inventive Hybrid Analog Digital Format-Multi-channel audio including header with compression table (top line). Looking at the HAD audio signal, one will realize that the top line has a repetitive pattern, which gives the first hint on how the signal shall be decoded by non-linear compression tables. More on that later. Furthermore, one will realize that the following two lines represent some sort of wave and not a random signal, which fed into an analog amplifier and loudspeaker will give a wide range of sounds. Using the hearing range of human beings (up to 20,000 kHz) and applying Shannon-Nyquist criterium will allow an engineer to at least find the speed respectively sampling frequency of the signal. When combined with an HAD video (FIG. 2), the framerate can be determined at 24 frames per second. Assuming a 4 K Video with (4,096×2,160 pixel) sampling rate is approximately 48 kHz (2160*24) or 96 kHz (4096*24) for a 10×10 matrix and 48 kHz (4096*24) for a 20×20 matrix. One will also realize that each individual line will represent a Left or Right audio signal or in case of FIG. 3b a multi-channel audio signal today commonly used in Surround Sound.

FIG. 3c shows another example of the Hybrid Analog Digital Format together with an explanation of the compression table (top line). The header contains all information required to identify that the given PCM samples need to be expanded according to the 2ⁿ weight function indicated by horizontal lines. These lines are doubled step by step, which is a clear sign that the 2ⁿ weight function needs to be applied dependent on the location of the respective lines or pixels.

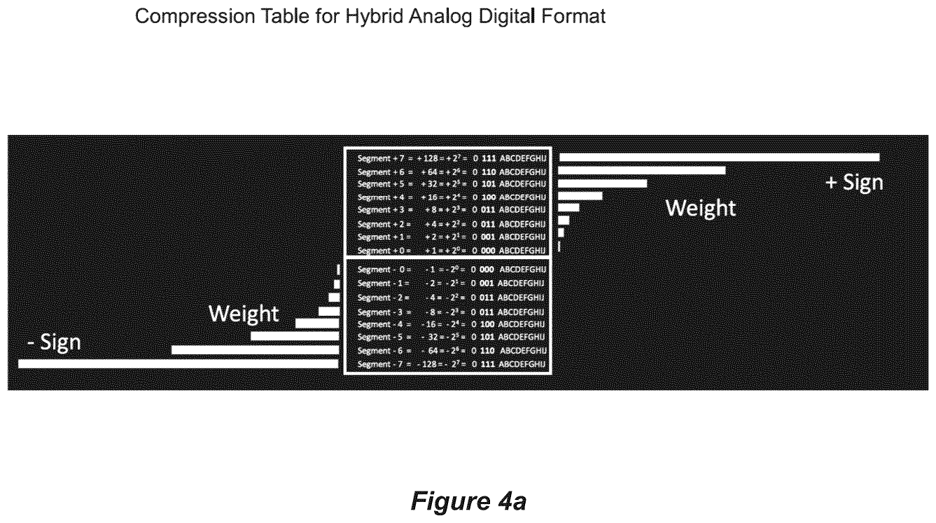

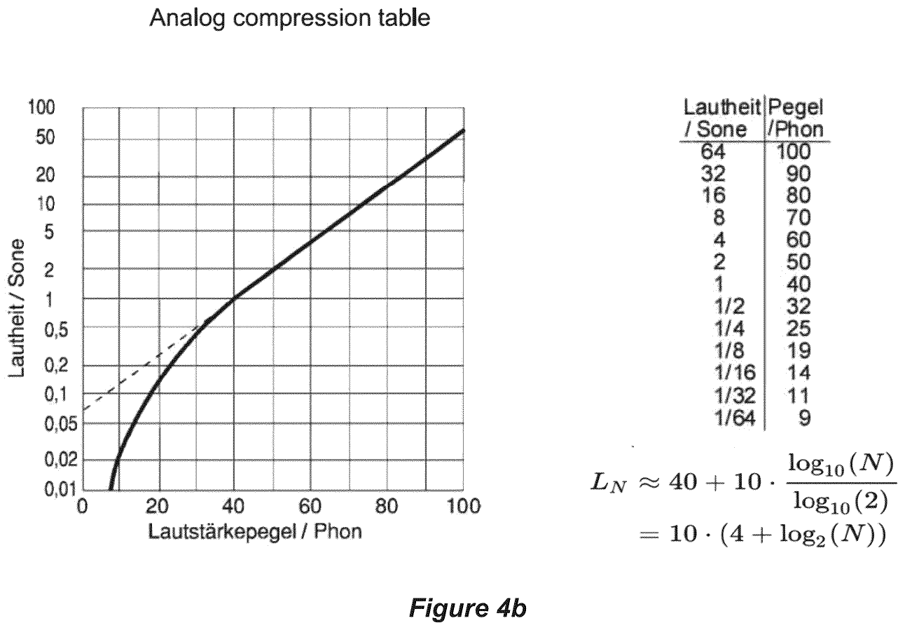

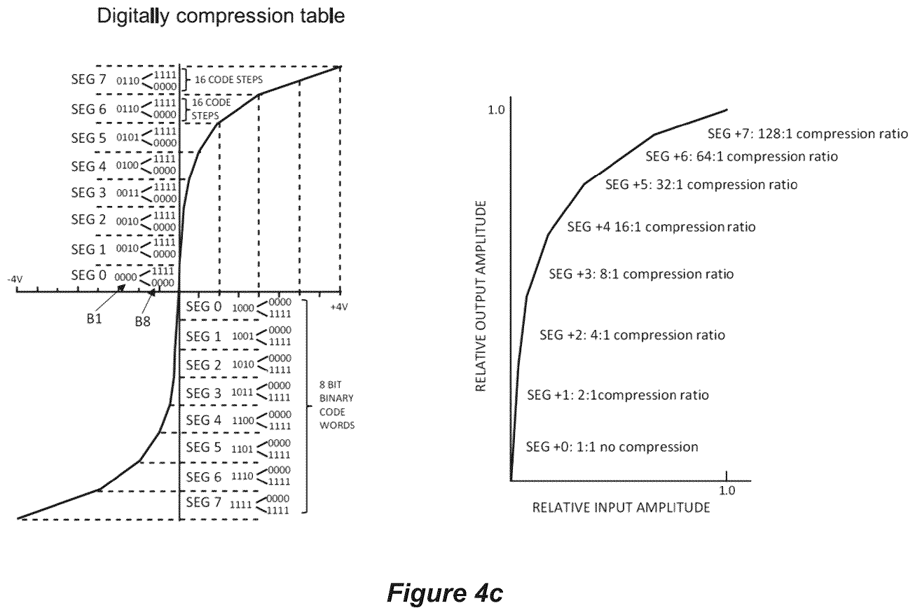

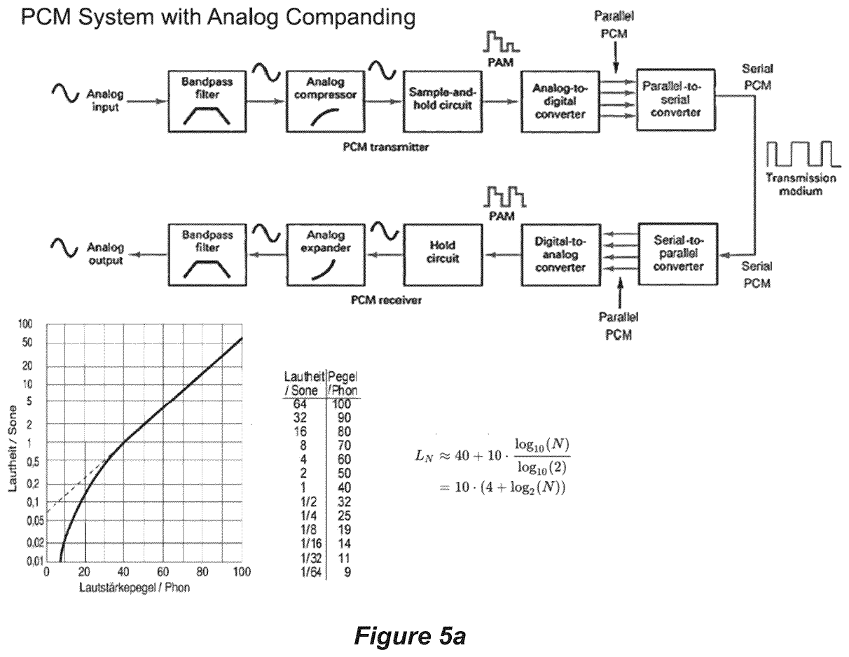

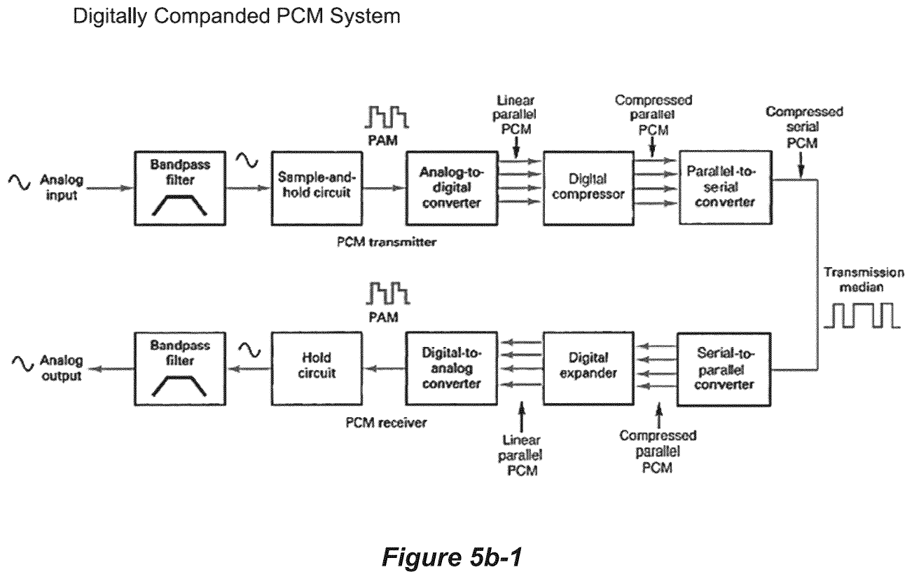

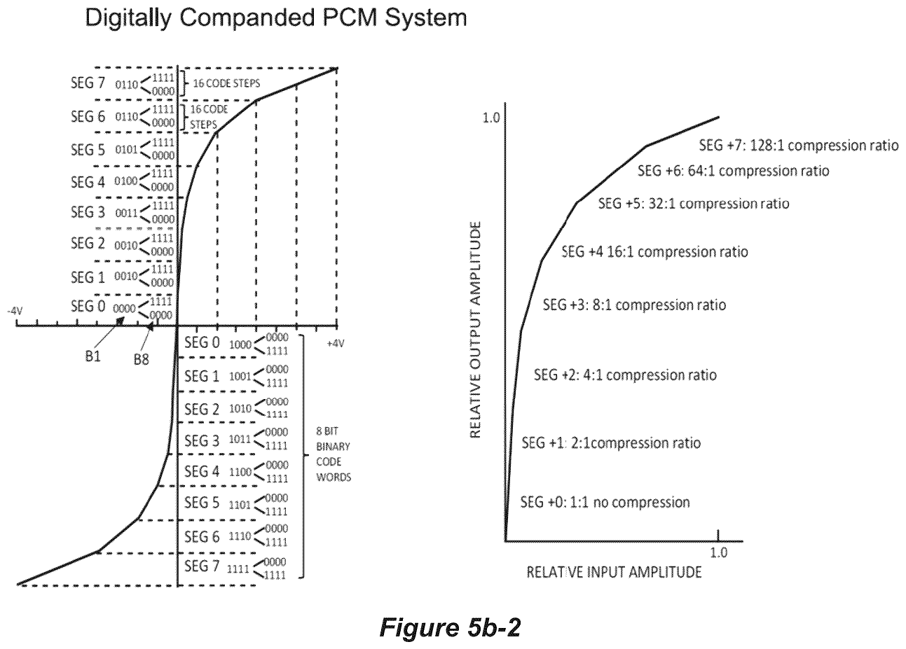

FIG. 4a shows an example of a compression table for the Hybrid Analog Digital Format. FIG. 4b shows an analog compression table, FIG. 4c a digital compression table. An engineer familiar with non-linear PCM coding will immediately realize that the 2ⁿ horizontal line length is similar to the analog and digital compression/expansion tables used in the well-known “companding” PCM coding. This is illustrated in FIG. 5a (PCM System with Analog Companding) and FIGS. 5b-1 and 5b-2 (Digitally Companded PCM System).

PCM Systems with analog companding utilize the following steps:
Compression path
Audio input
Bandpass filter
Analog compressor (see function to the right)
Sample & Hold
Analog to digital converter
Parallel to serial converter
Expansion path
Serial to Parallel converter
Digital to analog converter
Hold circuit
Analog expander (see function to the right)
Bandpass filter
Audio output

PCM Systems with digital companding utilize the following steps:
Compression path
Audio input
Bandpass filter
Sample & Hold
Analog digital converter
Digital compressor (see function to the right)
Analog digital converter
Parallel to serial converter
Expansion path
Serial to Parallel converter
Digital Expander (see function to the right)
Digital to analog converter
Hold circuit
Bandpass filter
Audio output

Some or all of these steps may also be employed in the context of the present invention.

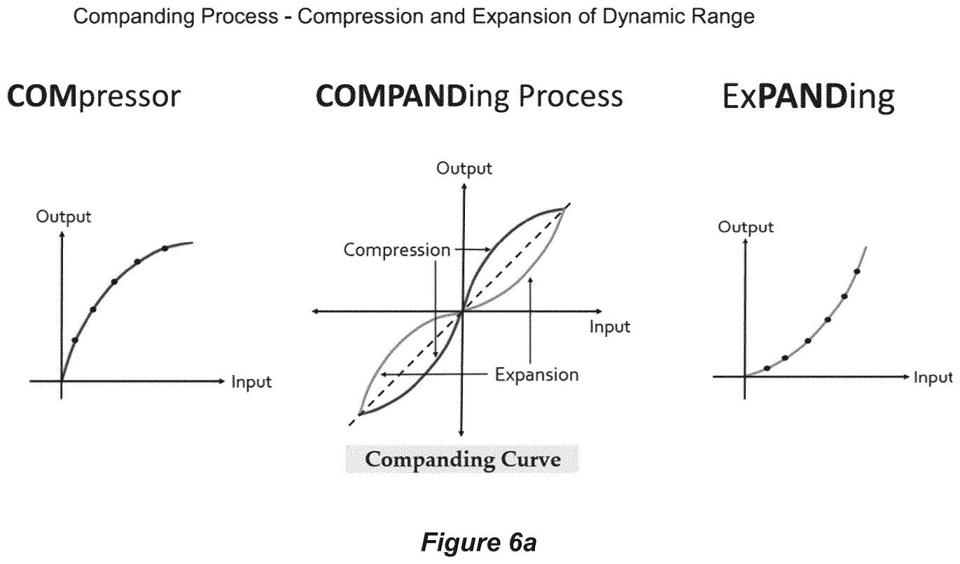

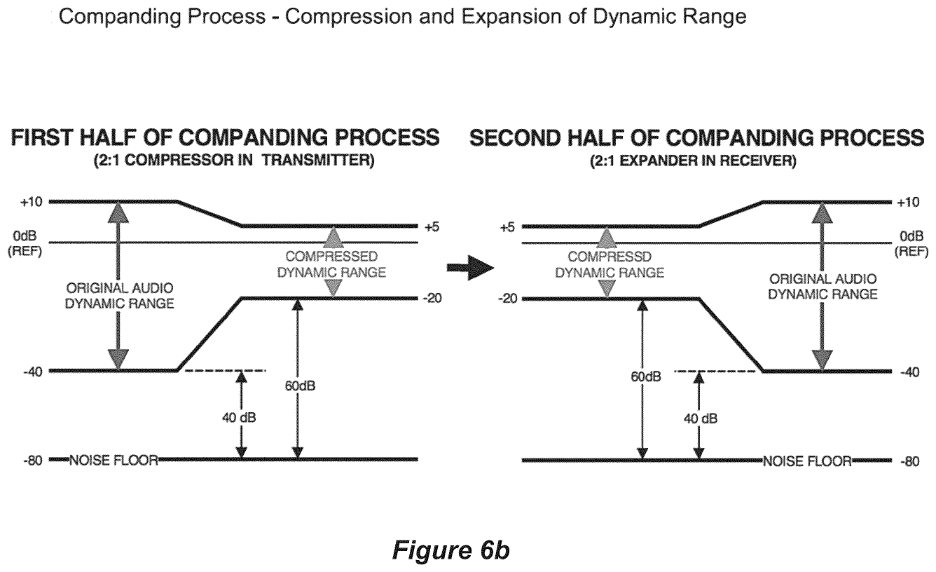

FIGS. 6a and 6b illustrate the Companding Process in more detail. The companding process consists of a compression step, which resolves low volumes in more detail and thus reduces the interference by noise (Non-linear Compressor). After transport or storage, the compressed signal is expanded and thus recreates the full dynamic range of the original signal (Non-linear Expansion). The combination of compression and expanding basically reconstructs the initial system as displayed in the middle graph.

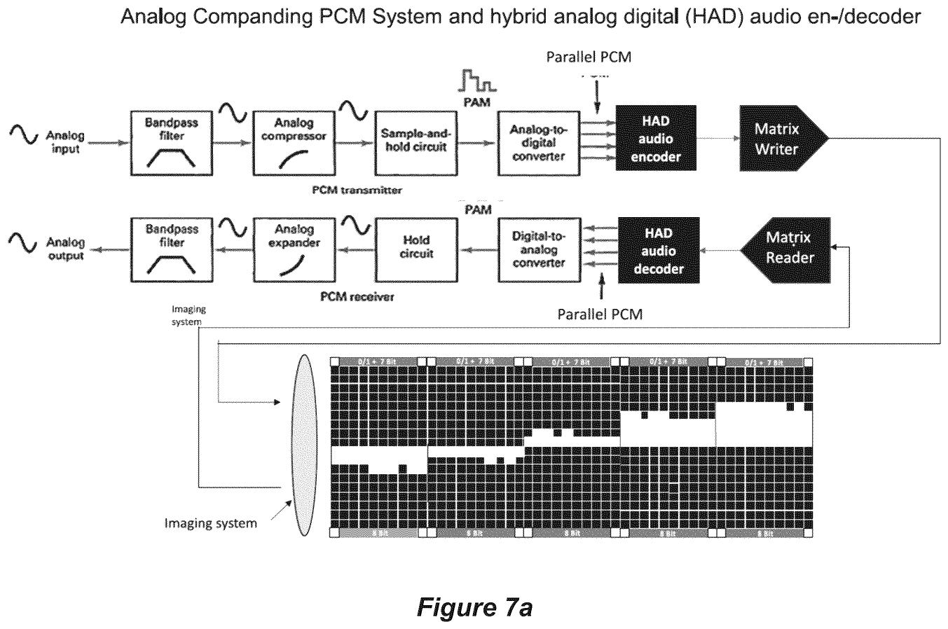

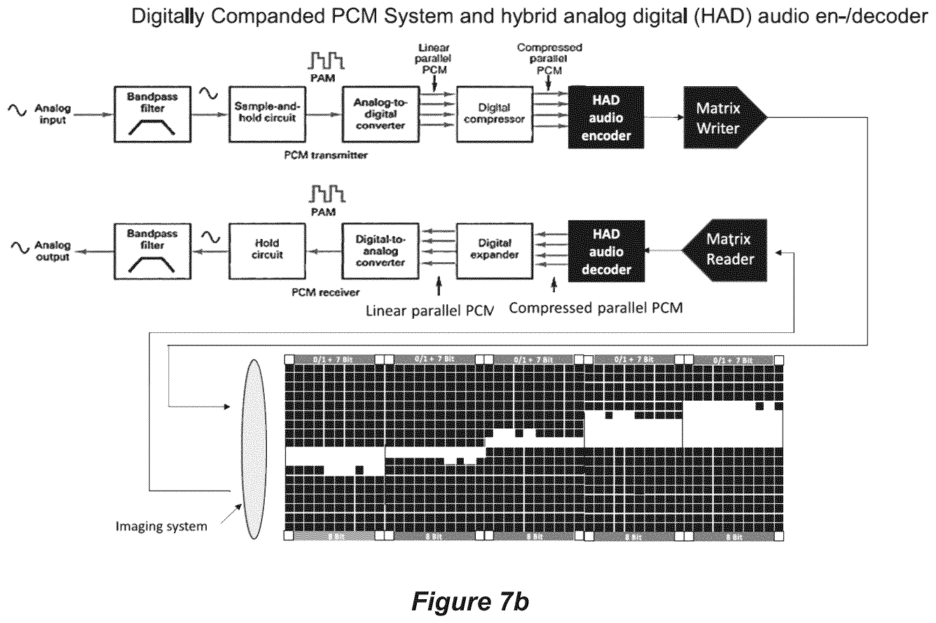

FIG. 7a illustrates the transfer of the Analog Companding PCM System to the hybrid analog digital (HAD) audio en-/decoder. The analog companding process can not only be applied to data transport, but also to writing and reading data in a particular hybrid analog digital (HAD) format. Instead of a parallel-serial converter (FIG. 5a), we use a hybrid analog digital (HAD) encoder and an HAD writer as described in more detail below. The decoding preferably works as a combination of HAD reader und a hybrid analog digital (HAD) decoder as described in more detail below.

FIG. 7b depicts a Digitally Companded PCM System and a hybrid analog digital (HAD) audio en-/decoder. The digital companding process can not only be applied to data transport, but also to writing and reading data in a particular hybrid analog digital (HAD) format. Instead of a parallel-serial converter (FIG. 5b-1), we use a hybrid analog digital (HAD) encoder and a HAD writer as described in more detail below. The decoding preferably works as a combination of HAD reader und a hybrid analog digital (HAD) decoder as described in more detail below.

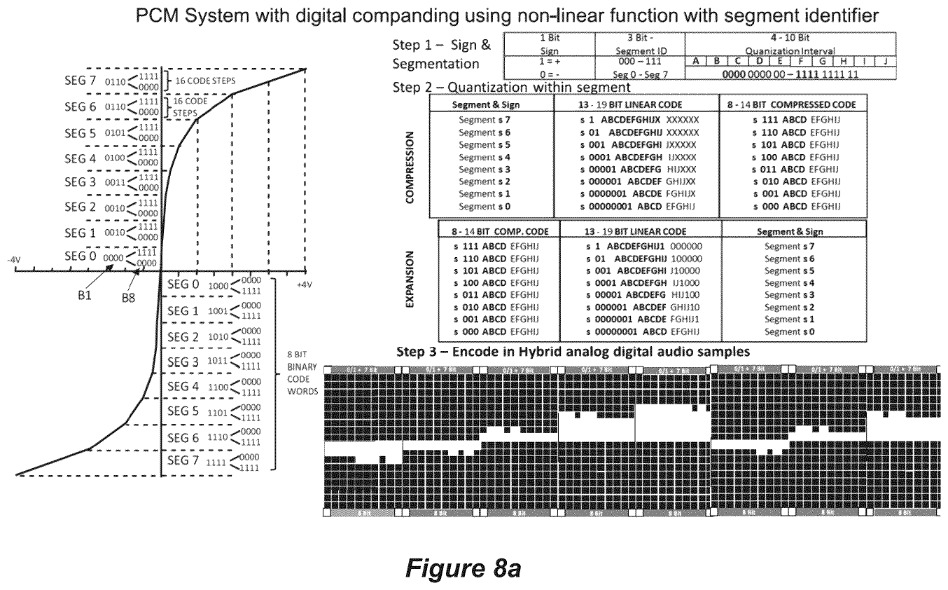

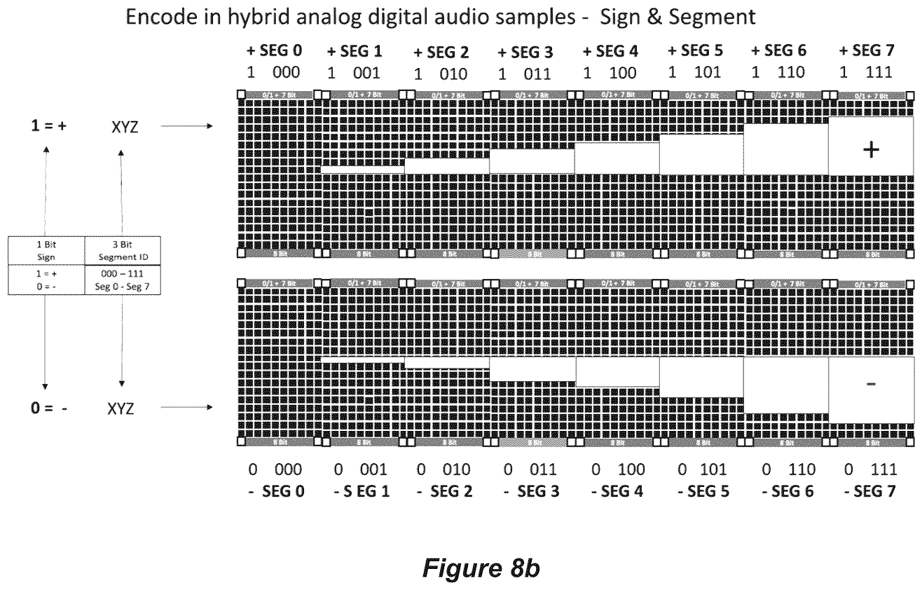

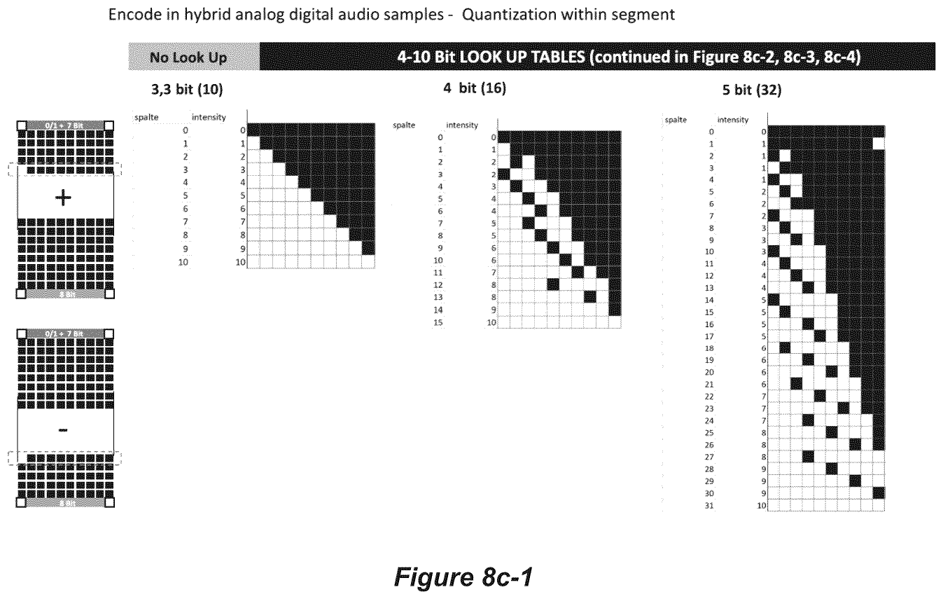

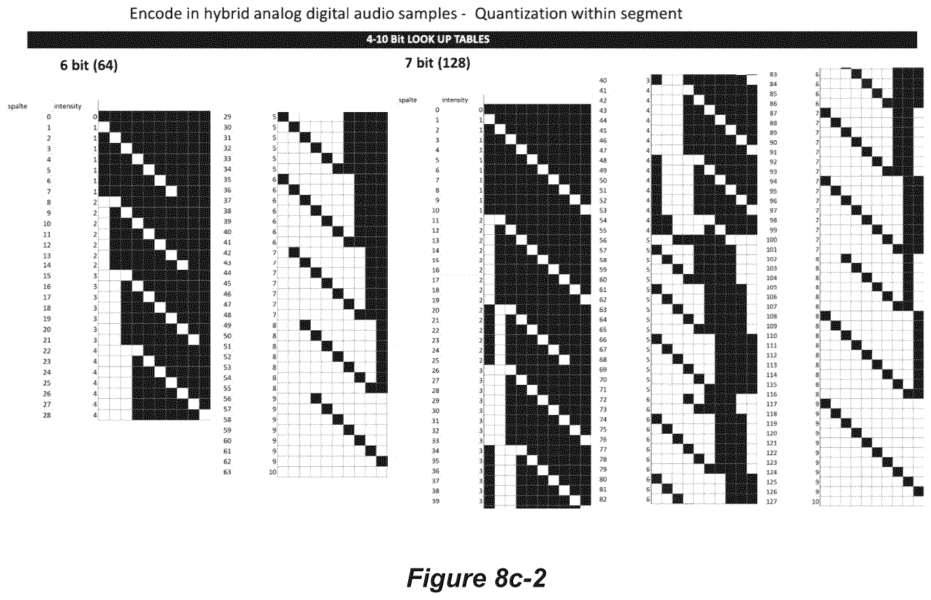

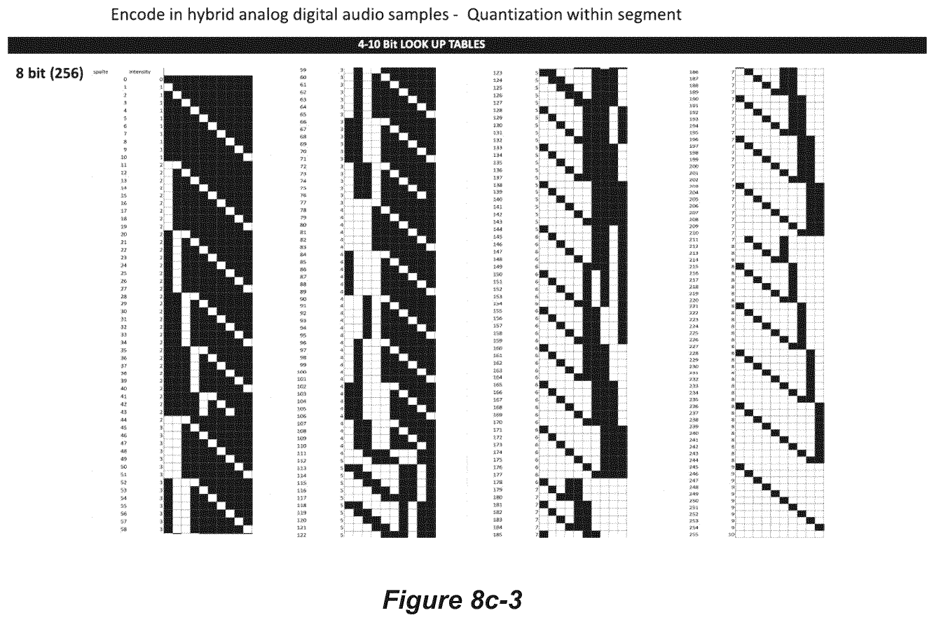

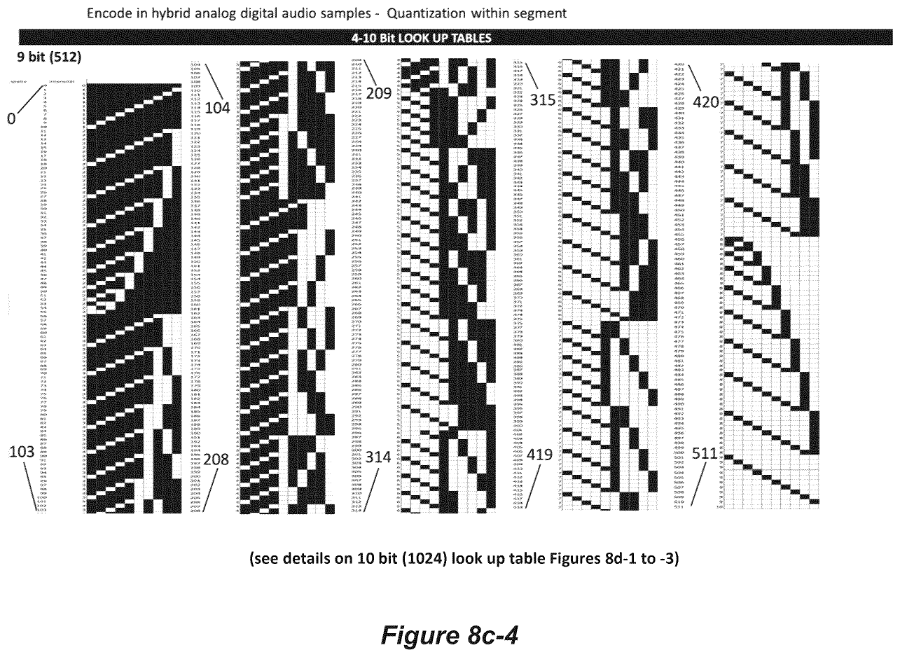

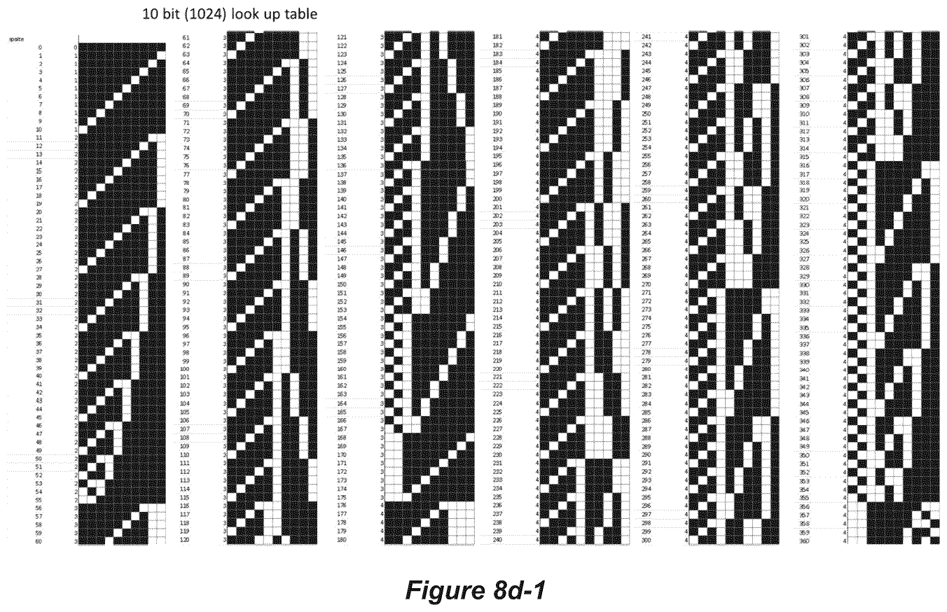

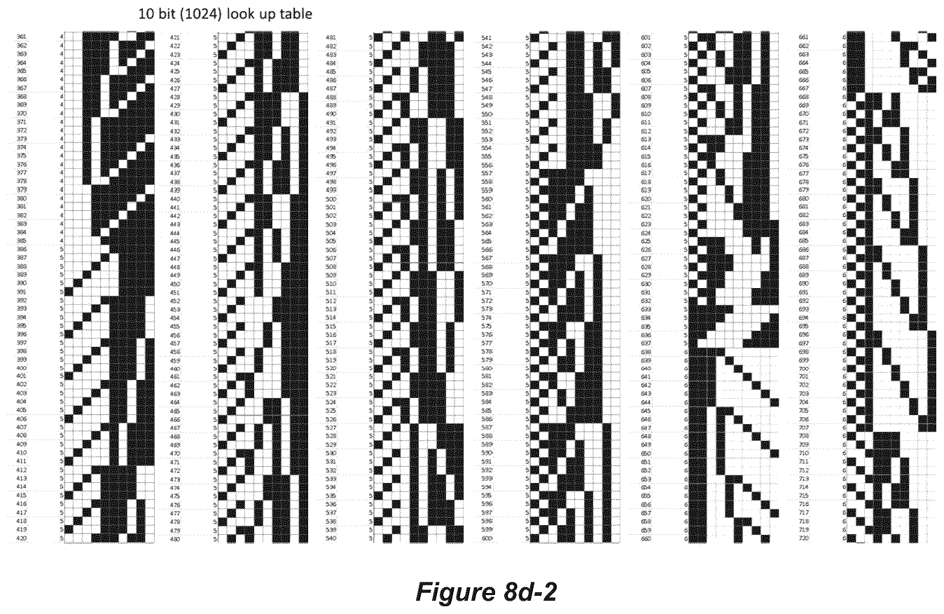

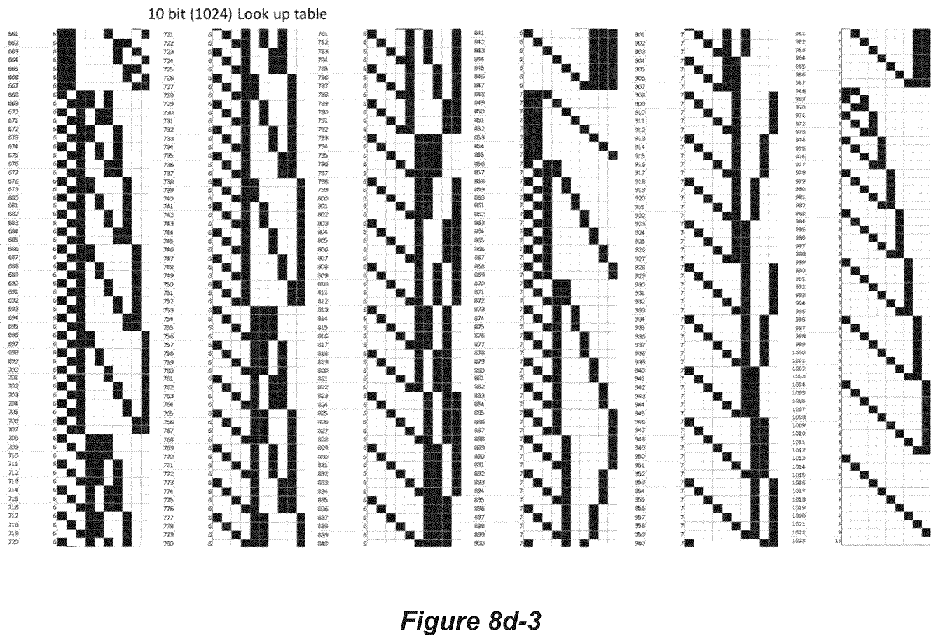

FIG. 8a shows a PCM System with digital companding using a non-linear function with segment identifier. Digital companding uses a three-step approach of compression:
Step 1—Sign & Segmentation
a. Identify the sign of the audio sample with 1 Bit sign (e.g., 1/0=+/−)
b. Using the non-linearity of the next 3-4 Bits allows to use 0-7 or even 0-15 segments
Step 2—Quantization within segment
4-10 Bits can be used for quantification within each segment by using 0-10 pixel per line
Step 3-Encode in Hybrid Analog Digital Audio samples
Sign, segment and quantification with segment are encoded in Hybrid Analog Digital Audio samples as described below in more detail.

FIGS. 8b and 8c-1 to 8c-4 illustrate the encoding in hybrid analog digital audio samples—Sign and Segment (FIG. 8b) and Quantization within segment (FIGS. 8c-1 to 8c-4).
Step 1—Sign & Segmentation
a. The sign is represented by using the upper or lower matrix as indicated in FIG. 8b
b. The segment is basically filled up completely up to the number of the segment 0-7 (3 Bits) or 0-15 (4 Bits)
Step 2—Quantization within segment
3,3-10 Bits can be used for quantification within each segment.
A. No Look up table: The number of white pixels can vary between 0 -10 enabling 3,3 Bits information storage, without requiring a look up table.
B. 4-10 Bits Look up table: Obviously the white pixels can be arranged in a multitude of ways representing 0-10 intensity levels, with two exceptions, which are all pixels being white or black. Many different look up tables can be generated, as long as intensity corresponds to the quantity level. Thus, the intensity level is the first approximation, while the exact arrangement gives more resolution of the quantization levels.
4 Bit: 16 quantization levels can be represented with 10 intensity levels
5 Bit: 32 quantization levels can be represented with 10 intensity levels
6 Bit: 64 quantization levels can be represented with 10 intensity levels
7 Bit: 128 quantization levels can be represented with 10 intensity levels
8 Bit: 256 quantization levels can be represented with 10 intensity levels
9 Bit: 512 quantization levels can be represented with 10 intensity levels
10 Bit: 1024 quantization levels can be represented with 10 intensity levels

FIGS. 8 c-1 to 8 c-4 shows exemplary look-up tables for 4-10 Bits. As will be evident to the skilled person, there are numerous options for each of these look-up tables. For example, looking at the look-up table for 4 Bits, there is apparently only one way to arrange 10 white pixels (bottom line) or 10 black pixels (top line). Yet, there are already ten different options to place a single white pixel (line 15) or a single black pixel (line 2) within that line having ten columns. However, only one of these ten options is used in the 4 Bit code because altogether only 16 different patterns are necessary to achieve 4 Bits.

Apparently, any other pattern would also be suitable in the context of the present invention. It is however preferred that the number of marked elements per line is continuously growing from bottom to top or vice versa (see the example in FIG. 8c-1: 0-1-2-2-3-4-4-5-5-6-6-7-8-8-9-10). It is further preferred to achieve an even distribution of the number of pixels per line. Of course, this is not entirely possibly for, e.g., the 9 Bit code, where there are just one and 10 possible patterns for the two bottom-most and the two top-most lines. Thus, in this case the distribution will start approximating a Gaussian function such as 1-10-45-80-80-80-80-80-45-10-1 (summing up to 512 alternative patterns). Again, the specific look-up table will not be decisive for the quality of the code but it is preferred to have a continuous increase and to achieve a distribution that is as even as possible.

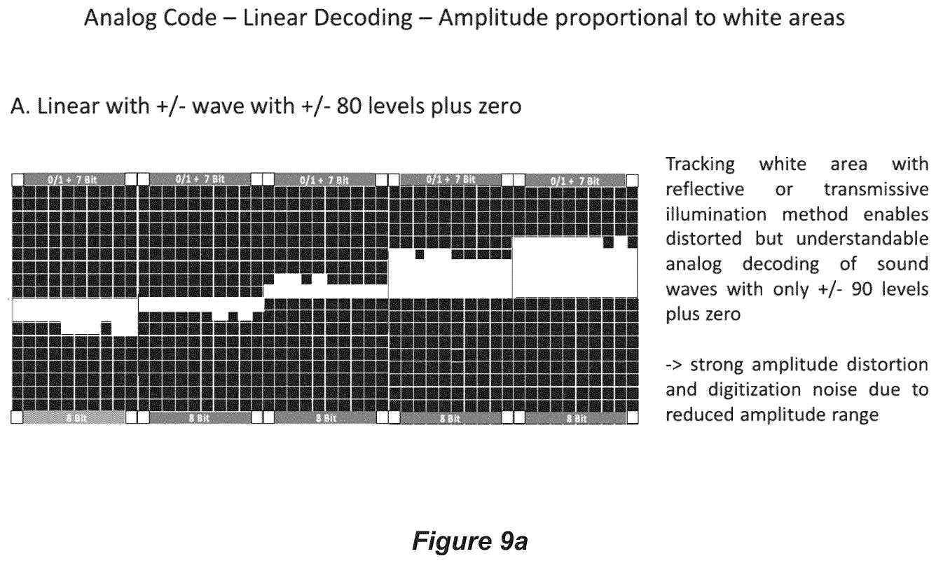

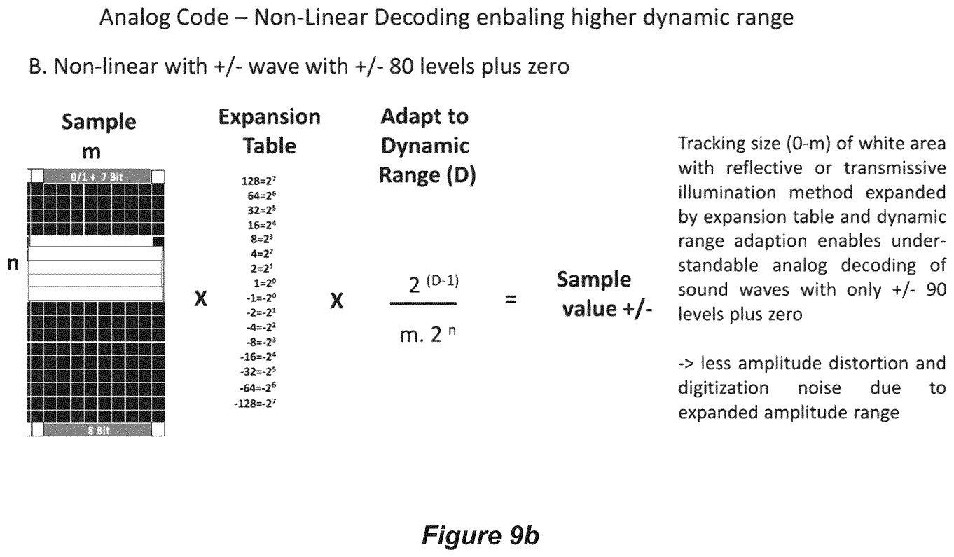

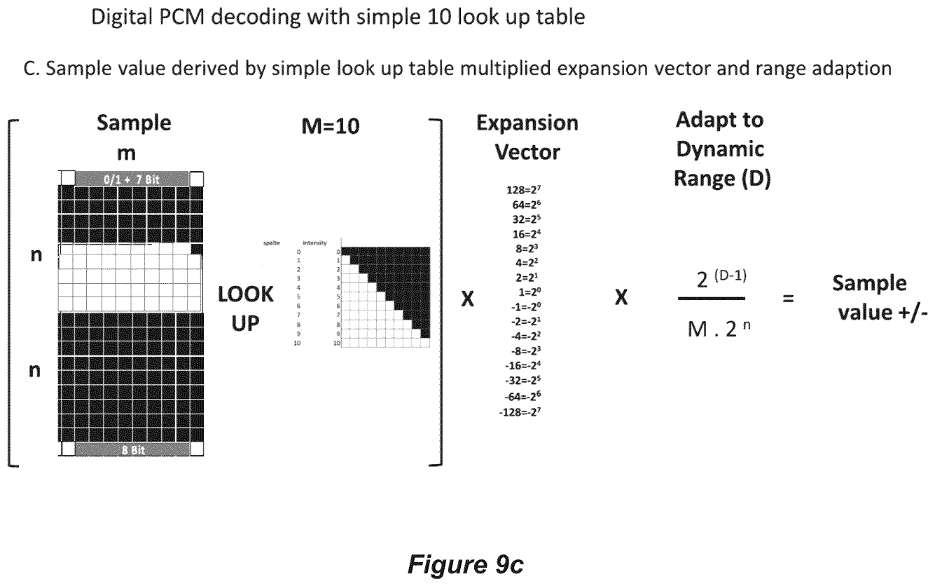

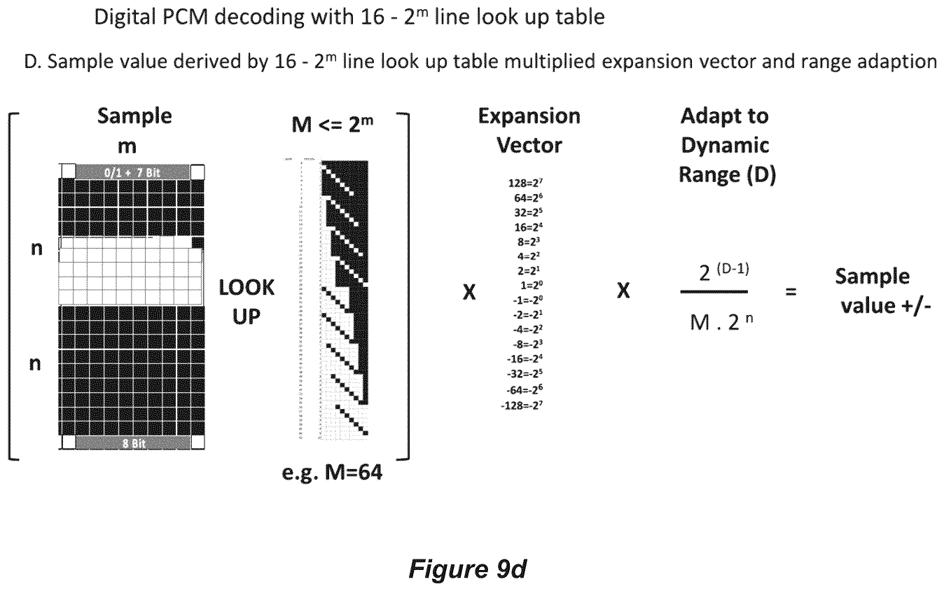

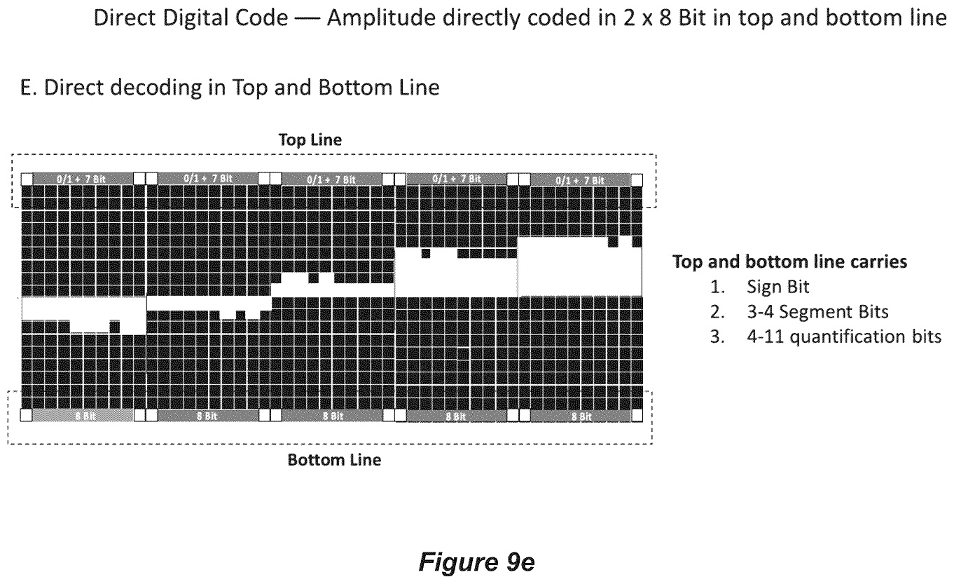

FIG. 9a shows an example of Analog Code—Linear Decoding—Amplitude proportional to white areas.

### A. Linear with +/−Wave with +/−80 Levels Plus Zero

An engineer looking at the wave form of the sample sequence realizes quickly that the stored signal can be decoded in an analog manner by feeding the intensity (white) into an amplifier and a loudspeaker. Tracking white areas with reflective or transmissive illumination methods enables distorted but understandable analog decoding of sound waves with only +/−90 levels plus zero. The sound has of course a strong amplitude distortion and digitization noise due to reduced amplitude range (only +/−80 levels plus zero).

FIG. 9b shows an example of Analog Code—Non-Linear Decoding enabling higher dynamic range.

### B. Non-Linear with +/−Wave with +/−80 Levels Plus Zero

An engineer looking at the wave form of the sample sequence and considering the expansion table in the header (see FIG. 3c-FIG. 4a) will realize after some consideration that the sound quality can be improved by decoding the analog samples sequence by weighting each line with the expansion table. Tracking size (0-m) of white area with reflective or transmissive illumination method expanded by expansion table and dynamic range adaption enables understandable analog decoding of sound waves with only +/−80 levels plus zero. The sound has less amplitude distortion compared to linear decoding and digitization noise due to expanded amplitude range.

FIG. 9c shows an example of Digital PCM decoding with simple 10 look-up table.

### C. Sample Value Derived by Simple Look Up Table Multiplied Expansion Vector and Range Adaption

An engineer looking at the wave form of the sample sequence and considering the expansion table in the header (see FIG. 3c-FIG. 4a) will realize after some consideration that the sound quality can be improved by decoded the digital samples sequence by weighting each number of pixels per line (intensity 0-10) with the expansion table. Tracking size (0-m) of white area with reflective or transmissive illumination method expanded by expansion table and dynamic range adaption enables understandable digital decoding of sound waves with only +/−80 levels plus zero. In order to adopt the decoded sample value to the original dynamic range a multiplication with the following factor is required: 2^{D-1}/M.2ⁿ. The sound has very little amplitude distortion compared to analog decoding and digitization noise due to expanded amplitude range.

FIG. 9d shows an example of Digital PCM decoding with 16-2^{m} lines look-up table.

### D. Sample Value Derived by 16-2^{m} Lines Look-Up Table Multiplied Expansion Vector and Range Adaption

An engineer looking at the wave form of the sample sequence and considering the expansion table in the header (see FIG. 3c-FIG. 4a) and the Look-up tables (see FIG. 8d-1 to 8d-3) will realize after some consideration that the sound quality can be improved furthermore by decoded the digital samples sequence by weighting each quantization levels derived from the Look-up tables (see FIG. 8d-1 to 8d-3) with the expansion table (see FIG. 4a). Tracking size (0-m) of white area with reflective or transmissive illumination method expanded by expansion table and dynamic range adaption enables understandable analog decoding of sound waves with only +/−8×M levels plus zero. In order to adopt the decoded sample value to the original dynamic range a multiplication with the following factor is required: 2^{D-1}/M.2ⁿ. D being the dynamic range in bit (e.g. 16 bit) The sound has almost no amplitude distortion compared to linear decoding and digitization noise due to expanded amplitude range.

Finally, FIG. 9e shows an example of Direct Digital Code—Amplitude directly coded in 2×8 Bit in top and bottom line.

### E. Direct Decoding in Top and Bottom Line

An engineer looking at samples of hybrid analog digital signal in the sequence of 2×n×m matrices (e.g. 10×10) will realize the correlation between that signal and the top and bottom-line bit values. This enables a direct decoding of the signal by only decoding these two lines and using the n×m matrix (e.g. 10×10) as error correction mechanism. The sound has no amplitude distortion and minimal digitization noise.

The applicant has tested the encoding and decoding according to the present invention with Mozart's composition “Eine kleine Nachtmusik”. The Encoder has been written in Python 3.8. All tests have been conducted on an Apple MI Max Processor.

### Encoding Setup

The encoding process commences by importing a music file in .wav format using a bit-depth of 16 bits and representing it as a 1-dimensional vector of digital PCM values further referred to as PCM vector. The source code further constructs the lookup-table for translating the digital PCM values to HAD audio format values. The table, also referred to as scaling matrix, is constructed as a 63×9 2d matrix that only contains the positive PCM values ranging from 1 to 32193 (the maximum positive bit value). To create the negative scaling matrix, the algebraic signs are simply inverted. The 9 rows represent the different scaling levels.

### Encoding a PCM Value

The source code next generates a template for pixel blocks to represent binary values. One pixel block consists of 10×1 pixels and a white pixel represents “1”, while a black pixel represents “0”.

Next, the source code iterates through the PCM vector. For each value in the PCM vector, it finds the closest value on either the negative or positive scaling matrix.

This scaling value is then used as a basis for constructing a 10×20 2d pixel matrix using the previously generated blocks.

For each level in the scaling matrix, one 10×1 row of white pixels is added to the pixel matrix.

Once the row is reached in the scaling matrix where the previously identified scaling value is located, the next row is added to the pixel matrix representing the position of the value in the row using a binary encoding with 10 values. The translation of the value in that row to the 10 digit bitcode is done according to the look-up table.

During the test, the encoding and decoding worked perfectly fine and the composition was clearly discernable after decoding.

1-20. (canceled)

21. A method of storing a digital audio signal in a hybrid format, the method comprising:
providing a digital audio signal with a series of audio signal samples, each audio signal sample having one Sign Bit representing a sign of the audio signal sample, three to four Segment Bits representing a number of segments of the audio signal sample, and four to ten Quantification Bits representing a quantification of a relevant segment of the audio signal sample; and
storing each audio signal sample of the digital audio signal in a double matrix, each matrix of the double matrix containing m columns and n lines, wherein one matrix of the double matrix comprises a positive signal matrix that represents a positive audio signal sample and the other matrix of the double matrix comprises a negative signal matrix that represents a negative audio signal sample, wherein each line of each matrix represents one of the segments of the audio signal sample;
wherein storing each audio signal sample in the double matrix comprises:
selecting one of the matrices of the double matrix to represent the sign represented by the Sign Bit,
marking all elements of all lines of the selected matrix representing the segments with the Segment Bits, and
marking one or more elements in one further line of the selected matrix representing the relevant segment adjacent to the segments marked by the Segment Bits with a predetermined pattern corresponding to the quantification of the relevant segment represented by the Quantification Bits.

22. The method of claim 21, wherein there are a plurality of predetermined pattern and a plurality of quantifications, wherein each predetermined pattern for each quantification is defined in a look-up table.

23. The method of claim 21, wherein the positive signal matrix and the negative signal matrix are arranged adjacent to each other and are separated by a hypothetical separation line, wherein the lines representing the segments are filled up starting from the separation line.

24. The method of claim 21, wherein each audio signal sample represents an amplitude, wherein the amplitude scales exponentially with the number of fully marked lines.

25. The method of claim 21, wherein each audio signal sample represents an amplitude, wherein a number of the marked elements within each predetermined pattern grows continuously with increasing amplitude.

26. The method of claim 21, wherein the series of audio signal samples of the digital audio signal are stored in adjacent double matrices.

27. The method of claim 21, wherein storing each audio signal sample of the digital audio signal comprises providing a data carrier and creating a plurality of recesses in a surface of the data carrier using a laser to mark the marked elements of the double matrix.

28. The method of claim 27, wherein a shape of the recesses is cylindrical or cone-like.

29. The method of claim 27, wherein providing the data carrier comprises providing a substrate and coating the substrate with a first coating of a material different from a material of the substrate, wherein creating the plurality of recesses in the surface of the data carrier comprises creating the plurality of recesses in the first coating.

30. The method of claim 29, wherein the recesses extend through the coating to the substrate.

31. The method of claim 29, wherein the substrate is a ceramic substrate.

32. The method of claim 29, wherein the substrate comprises one or a combination of: a glassy transparent ceramic material, a crystalline ceramic material, sapphire (Al₂O₃), silica (SiO₂), zirconium silicate (Zr(SiO₄)), ZrO₂, boron oxide, sodium oxide, potassium oxide, lithium oxide, zinc oxide, and magnesium oxide.

33. A method of reading out analog audio information from a digital audio signal in a hybrid format stored according to claim 21, the method comprising:
generating an audio amplitude based on a number of the marked elements within the double matrix,
wherein a sign of the audio amplitude is defined by the selected matrix of the double matrix containing the marked elements.

34. The method of claim 33, wherein the number of the marked elements within the double matrix is extracted by illuminating the double matrix from one side and measuring a reflected light or a transmitted light amplitude on the opposite side.

35. The method of claim 33, wherein generating the audio amplitude is repeated for each of a series of double matrices to generate an audio signal with a series of samples.

36. A method of reading out enhanced analog audio information from a digital audio signal in a hybrid format stored according to claim 21, the method comprising:
generating an audio amplitude based on a number of marked lines representing the segments and on a number of the one or more marked elements within the further line within the double matrix,
wherein a sign of the audio amplitude is defined by the selected matrix of the double matrix containing the marked elements, and wherein the audio amplitude is based on weighting each line with a different weighting coefficient.

37. The method of claim 36, wherein the weighting coefficients for lines 0, 1, 2, . . . , n−1 scale with 2⁰, 2¹, 2², . . . , 2ⁿ⁻¹.

38. The method of claim 36, further comprising:
generating the audio amplitude based on the number of marked lines representing the segments, and on the number of the one or more marked elements within the further line, and on a pattern of the marked elements within the further line within the double matrix,
wherein the sign of the audio amplitude is defined by the selected matrix of the double matrix containing the marked elements, and wherein the audio amplitude is based on weighting each line with the different weighting coefficients and on allocating a predetermined amplitude to the pattern of the marked elements based on a look-up table.

39. The method of claim 38, wherein the weighting coefficients for lines 0, 1, 2, . . . , n−1 scale with 2⁰, 2¹, 2², . . . , 2ⁿ⁻¹.

40. The method of claim 38, wherein the allocated predetermined amplitude increases continuously with the number of the one or more marked elements within the pattern.
